(19) United States
(12) Patent Application Publication
(10) Pub. No.: US 2008/0107582 A1
(43) Pub. Date: May 8, 2008

(54) Method for manufacturing semiconductor single crystal by Czochralski technology, and single crystal ingot and wafer manufactured using the same

(75) Inventors: Young-Ho Hong, Gumi-si (KR); Sang-Jun Lee, Gumi-si (KR); Seong-Oh Jeong, Gumi-si (KR); Hong-Woo Lee, Gumi-si (KR)

Correspondence Address: GREER, BURNS & CRAIN, 300 S WACKER DR, 25TH FLOOR, CHICAGO, IL, 60606, US

(73) Assignee: Siltron Inc.

(21) Appl. No.: 11/974,921

(22) Filed: Oct. 16, 2007

(30) Foreign Application Priority Data
Oct. 17, 2006 (KR) 10-2006-0100912

(51) Int. Cl. C30B 15/00; C01F 17/00

(52) U.S. Cl. 423/263; 117/19; 423/279; 423/299; 423/348; 423/594.8; 420/556; 420/555

(57) ABSTRACT

A method for manufacturing a semiconductor single crystal uses a Czochralski (CZ) process in which a seed crystal is dip into a melt of semiconductor raw material and dopant received in a crucible, and the seed crystal is slowly pulled upward while rotated to grow a semiconductor single crystal. Here, a cusp-type asymmetric magnetic field having different upper and lower magnetic field intensities based on ZGP (Zero Gauss Plane) where a vertical component of the magnetic field is 0 is applied to the crucible such that a specific resistance profile, theoretically calculated in a length direction of crystal, is expanded in a length direction of crystal. Thus, thickness of a diffusion boundary layer near a solid-liquid interface is increased to increase an effective segregation coefficient of dopant, thereby expanding a specific resistance profile in a length direction of crystal, increasing a prime length of the single crystal, and improving productivity.

### BACKGROUND OF THE INVENTION

1. Field of the Invention

The present invention relates to a method for manufacturing a semiconductor single crystal, and more particularly to a method for manufacturing a semiconductor single crystal, which may expand a specific resistance profile per each single crystal length during the growth of single crystal using Czochralski technology (hereinafter, referred to as “a CZ process”), a single crystal ingot manufactured using the method, and a wafer made using the ingot.

2. Description of the Related Art

Generally, a silicon single crystal used as material for producing electronic components such as semiconductor is manufactured using the CZ process. The CZ process is conducted in a way that a polycrystalline silicon is put into a quartz crucible and melted over 1400° C., and then a seed crystal is dipped into the melted silicon melt and then slowly pulled to grow a crystal. It is well disclosed in “Silicon Processing for the VLSI Era (volume 1, Lattice Press (1986), Sunset Beach, Calif.), by S. Wolf and R. N. Tauber.

When growing a silicon single crystal using the CZ process, dopant of the III group or V group element such as B, Al, Ga, P, As and Sb is added depending on electric characteristic conditions of a semiconductor demanded by a consumer. When a silicon single crystal is grown, the added dopant is evenly added to the crystal. At this time, the dopant introduced into the crystal should not have too high concentration. At a concentration over a certain level, the dopant and silicon do not form a solid solution, but the dopant is extracted as a precipitate.

Generally, dopants evenly distributed in a silicon melt have different equivalent concentrations in a solid state and in a melted state. Thus, a ratio of a concentration of dopant in a melted state and a concentration of dopant in a solid state is defined as an effective segregation coefficient, and each dopant has a peculiar effective segregation coefficient according to the kind of element. Theoretically, if the effective segregation coefficient is 1, the dopant concentration in a silicon melt is equal to the dopant concentration in a silicon single crystal. However, dopants (B, P) used in growing a silicon single crystal have an effective segregation coefficient less than 1, and, as the effective segregation coefficient is less than 1, a dopant concentration in a silicon melt is higher than a dopant concentration in a silicon single crystal. In this reason, a silicon single crystal tends to show a higher dopant concentration in its lower portion than in its upper portion. A specific resistance of the silicon single crystal is affected by a concentration of dopant introduced into the single crystal. If a dopant having an effective segregation coefficient less than 1 is used, the silicon single crystal changes its specific resistance along a length of the crystal. For example, if boron is used as a dopant when growing a silicon single crystal, a specific resistance tends to decrease in a length direction of the crystal.

Meanwhile, in a semiconductor single crystal grown using the CZ process, only a crystal region satisfying a specific resistance condition as well as defect concentration condition and oxygen concentration condition, demanded by a consumer, may be used for making any product. Here, a length of a semiconductor single crystal satisfying all requirements of a customer is called ‘a prime length’. If a silicon single crystal is grown using a dopant having an effective segregation coefficient less than 1, a specific resistance is slowly decreased, when viewed in a length direction of the single crystal. At this time, in the crystal region having a specific resistance satisfying a certain condition, only a length of crystal region satisfying customer specifications such as defect concentration condition and oxygen concentration condition becomes a prime length.

However, the technique for controlling defect concentration and oxygen concentration is so far advanced, but the technique for controlling an effective segregation coefficient of a dopant to control a specific resistance profile in a length direction of a semiconductor single crystal is still staying at a beginning stage. Though a theoretic formula for an effective segregation coefficient of a dopant is made through experiments of crystal growth not greater than 3 inches, there is no precedent of a technique for controlling a specific resistance profile of a crystal by suggesting a control methodology of an effective segregation coefficient during single crystal growing. Thus, a prime length of a single crystal grown using the CZ process is dominated by a specific resistance profile mainly determined by an effective segregation coefficient of dopant. It is because other customer requirements may be easily controlled using a current single crystal growing technology.

For example, boron has an effective segregation coefficient in the range of 0.73 to 0.75, and a peculiar specific resistance profile is determined in a length direction of the single crystal according to such a specific numerical range, and a prime length allowing manufacture of a product is determined according to the specific resistance profile. Thus, the effective segregation coefficient of dopant acts as an essential factor that determines productivity per Kg when growing a semiconductor single crystal using the CZ process. As a result, if a specific resistance profile in a length direction of crystal is expanded by means of control of the effective segregation coefficient of dopant, the prime length may be increased as much. Here, expanding the specific resistance profile means that a specific resistance is increased at a certain ratio when measuring effective segregation coefficients before controlling and after controlling in a length direction of crystal from the same point.

In order to expand a specific resistance profile when growing a semiconductor single crystal using the CZ process, a specific nitrogen (N) or carbon (C) was conventionally added as impurities or a semiconductor ingot grown using a single crystal under an oxygen or nitrogen gas environment was thermally treated at a high temperature. As another method, a third element (e.g., Ba, P, Ge, or Al) was additionally added as a dopant in addition to the dopant basically added for control of the effective segregation coefficient, which is called ‘co-doping’.

These conventional methods have a limit that they may be used only for making a wafer having limited usages such as a high resistance wafer or a low resistance wafer. Also, the co-coping method shows characteristics, which are not required properties in making a semiconductor, or it is not sufficient for making a high quality ingot such as a defect-free ingot.

For a manufacturer who manufactures a semiconductor single crystal, it is important to improve the quality of crystal itself, but it is much more important to increase a prime length by expanding a specific resistance profile in a length direction of crystal so as to enhance productivity. However, since it is difficult to control an effective segregation coefficient, namely a specific resistance profile, as mentioned above, the prime length is inevitably fixed regardless of improvement of crystal quality, so there is basically a limit so far in enhancing productivity of products.

### SUMMARY OF THE INVENTION

The present invention is designed to solve the problems of the prior art, and therefore it is an object of the present invention to provide a method for manufacturing a semiconductor single crystal, which may expand a specific electric resistance profile in a length direction of crystal by controlling an effective segregation coefficient without adding a third element as a dopant as in the co-coping method, when making a large-caliber semiconductor single crystal over 200 mm as well as a small- or medium-caliber semiconductor single crystal using the CZ process; a semiconductor single crystal ingot manufactured using the method; and a wafer manufactured using the ingot.

Another object of the present invention is to provide a method for manufacturing a semiconductor single crystal, which may enhance productivity by expanding a prime length with keeping high quality for a variety of single crystal products regardless of classified defect regions, differently from the prior art in which a prime length of a single crystal capable of being manufactured into products was fixed based on a charge of the same material due to the difficulty in control of an effective segregation coefficient; a semiconductor single crystal ingot manufactured using the method; and a wafer manufactured using the ingot.

In order to accomplish the above object, the present invention provides a method for manufacturing a semiconductor single crystal using a Czochralski (CZ) process in which a seed crystal is dip into a melt of semiconductor raw material and dopant received in a crucible, and then the seed crystal is slowly pulled upward while being rotated to grow a semiconductor single crystal, wherein a cusp-type asymmetric magnetic field having upper and lower magnetic field intensities different from each other based on ZGP (Zero Gauss Plane) where a vertical component of the magnetic field is 0 is applied to the crucible such that a specific resistance profile, theoretically calculated in a length direction of crystal, is expanded in a length direction of crystal.

In the present invention, the theoretically calculated specific resistance is calculated using the following equation:

$${ρ}_{theory} = {{ρ}_{speed} ( 1 - S )}^{( 1 - {k}_{e} )}$$

where ρ_{theory} is a theoretic specific resistance, ρ_{seed} is a specific resistance of the seed crystal, S is a solidification ratio, kₑ is an effective segregation coefficient of the dopant.

Preferably, while a single crystal is growing, a temperature difference between a solid-liquid interface and a point spaced apart from the solid-liquid interface by 50 mm is less than 50K. Also, while a single crystal is growing, a ratio of a convection velocity at a solid-liquid interface to a convection velocity at a point spaced apart from the solid-liquid interface by 50 mm is less than 30.

Preferably, a specific resistance measured in 0 to ½ L region in a length direction of the grown semiconductor single crystal is increased 0 to 15% rather than the theoretically calculated specific resistance.

Preferably, a specific resistance measured in ½ L to 1 L region in a length direction of the grown semiconductor single crystal is increased 0 to 40% rather than the theoretically calculated specific resistance.

In one aspect of the present invention, a lower portion of the asymmetric magnetic field has a greater intensity than an upper portion thereof, based on ZGP. In this case, the ZGP has a parabolic pattern convex upward, and an upper vertex of the parabolic pattern is positioned above a semiconductor melt.

In another aspect of the present invention, an upper portion of the asymmetric magnetic field has a greater intensity than a lower portion thereof, based on ZGP. In this case, the ZGP has a parabolic pattern convex downward, and a lower vertex of the parabolic pattern is positioned in a semiconductor melt.

In the present invention, the semiconductor single crystal is Si, Ge, GaAs, InP, LN(LiNbO₃), LT(LiTaO₃), YAG (yttrium aluminum garnet), LBO(LiB₃O₅) or CLBO(CsLiB₆O₁₀) single crystal.

According to the present invention, an asymmetric magnetic field is applied when growing a semiconductor single crystal using the CZ process, thereby controlling a convection velocity and a temperature distribution of a semiconductor melt and thus restraining abnormal flowing of the semiconductor melt. Accordingly, a thickness of a diffusion boundary layer near a solid-liquid interface is increased to increase an effective segregation coefficient of dopant, and thus a specific resistance profile is expanded in a length direction of crystal. Thus, the present invention may improve productivity rather than the conventional one.

### BRIEF DESCRIPTION OF THE DRAWINGS

Other objects and aspects of the present invention will become apparent from the following description of embodiments with reference to the accompanying drawing in which:

FIG. 1 is a schematic view showing an apparatus for manufacturing a semiconductor single crystal, used for implementing a method for manufacturing a silicon single crystal according to a preferred embodiment of the present invention;

FIG. 2 shows simulation results of a magnetic field distribution around a silicon melt and a quartz crucible and ZGP (Zero Gauss Plane) in case a cusp-type asymmetric magnetic field is applied to the quartz crucible while growing a silicon single crystal;

FIG. 3 is a graph showing a theoretic specific resistance (♦) and an actually measured specific resistance (▪) according to a crystal direction of an 8-inch silicon single crystal made without applying a magnetic field thereto (a comparative example 1);

FIG. 4 is a graph showing a theoretic specific resistance (♦) and an actually measured specific resistance (▪) according to a crystal direction of an 8-inch silicon single crystal made by applying a cusp-type symmetric magnetic field (R=1) thereto (a comparative example 2);

FIG. 5 is a graph showing a theoretic specific resistance (♦) and an actually measured specific resistance (▪) according to a crystal direction of a silicon single crystal made by applying an asymmetric magnetic field (R=2.3) made according to a first embodiment of the present invention as shown in (a) of FIG. 2;

FIG. 6 is a graph showing a theoretic specific resistance (♦) and an actually measured specific resistance (▪) according to a crystal direction of an 8-inch silicon single crystal made by applying an asymmetric magnetic field (R=1.36) made according to a second embodiment of the present invention as shown in (b) of FIG. 2;

FIG. 7 is a graph showing simulation results of temperature distribution of a silicon melt in the first and second embodiments shown in FIG. 2, respectively; and

FIG. 8 is a graph showing simulation results of convection velocity distribution for the silicon melt in the first and second embodiments shown in FIG. 2, respectively.

### REFERENCE NUMERALS OF ESSENTIAL PARTS

SM: silicon melt
10: crucible
20: crucible housing
30: crucible rotating unit
40: heating unit
50: isolating unit
60: single crystal pulling unit
70: heat shield

### DESCRIPTION OF THE PREFERRED EMBODIMENT

Hereinafter, preferred embodiments of the present invention will be described in detail with reference to the accompanying drawings. Prior to the description, it should be understood that the terms used in the specification and the appended claims should not be construed as limited to general and dictionary meanings, but interpreted based on the meanings and concepts corresponding to technical aspects of the present invention on the basis of the principle that the inventor is allowed to define terms appropriately for the best explanation. Therefore, the description proposed herein is just a preferable example for the purpose of illustrations only, not intended to limit the scope of the invention, so it should be understood that other equivalents and modifications could be made thereto without departing from the spirit and scope of the invention.

Meanwhile, the embodiments of the present invention explained below are based on growth of a silicon semiconductor single crystal using the CZ process, however the spirit of the invention should not be interpreted to be limited only to the growth of a silicon semiconductor single crystal. Thus, it should be noted that the spirit of the present invention may be applied to all kinds of compound semiconductor single crystals including Si, Ge, GaAs, InP, LN (LiNbO₃), LT (LiTaO₃), YAG (yttrium aluminum garnet), LBO(LiB₃O₅) or CLBO(CsLiB₆O₁₀).

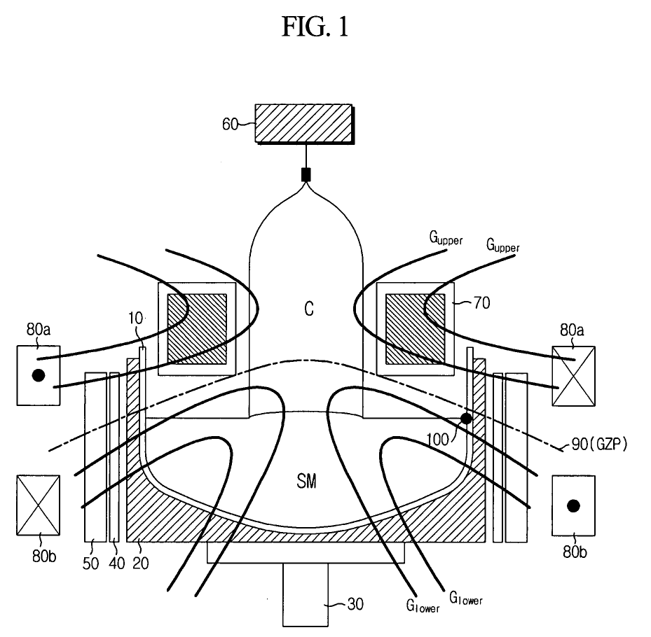

FIG. 1 is a schematic view showing an apparatus for manufacturing a semiconductor single crystal, which is used for implementing a method for manufacturing a silicon single crystal according to a preferred embodiment of the present invention.

Referring to FIG. 1, the semiconductor single crystal manufacturing apparatus includes a quartz crucible 10 for receiving a silicon melt (SM) obtained by melting a polycrystalline silicon and a dopant at a high temperature; a crucible housing 20 surrounding an outer circumference of the quartz crucible 10 and supporting the outer circumference of the quartz crucible 10 in a predetermined pattern; a crucible rotating unit 30 installed to a lower end of the crucible housing 20 to rotate the quartz crucible 10 together with the crucible housing 20; a heating unit 40 spaced apart from a sidewall of the crucible housing 20 by a predetermined length to heat the quartz crucible 10; an isolating unit 50 installed to an outer position of the heating unit 40 to prevent heat generated by the heating unit 40 from emitting out; a single crystal pulling unit 60 for pulling a single crystal (C) from the SM received in the quartz crucible 10 using a seed crystal; and a heat shield 70 spaced apart from an outer circumference of the single crystal (C) pulled by the single crystal pulling unit 60 by a predetermined length to reflect heat emitted from the single crystal (C). These components are commonly used in a semiconductor single crystal manufacturing device using the CZ process, well known in the art, so they are not described in detail here.

The semiconductor single crystal manufacturing apparatus employed in the present invention further includes magnetic field applying units 80a, 80b (hereinafter, designated by a reference numeral 80 in common) for applying a magnetic field to the quartz crucible 10, in addition to the above components. Preferably, the magnetic field applying unit 80 applies an asymmetric magnetic field Gᵤₚₚₑᵣ, G_{lower} (hereinafter, designated as G in common) to the high temperature SM received in the quartz crucible 10.

Preferably, the asymmetric magnetic field G has a greater intensity of the magnetic field G_{lower} in its lower portion than an intensity of the magnetic field Gᵤₚₚₑᵣ in its upper portion, based on ZGP (Zero Gauss Plane) 90. That is to say, R (=G_{lower}/Gᵤₚₚₑᵣ) of this magnetic field is greater than 1. Under such an asymmetric magnetic field condition, the ZGP 90 has an approximate parabolic pattern convex upward. Also, the magnetic field formed in the upper and lower portions based on the ZGP is asymmetrically distributed.

As an alternative, the asymmetric magnetic field G may has a greater intensity of the upper magnetic field Gᵤₚₚₑᵣ than that of the lower magnetic field G_{lower}. That is to say, the asymmetric magnetic field G may have R (=G_{lower}/Gᵤₚₚₑᵣ) less than 1. Under this asymmetric magnetic field condition, though not shown in the drawings, the ZGP 90 has an approximate parabolic pattern convex downward.

Preferably, the magnetic field applying unit 80 applies a cusp-type asymmetric magnetic field G to the quartz crucible 10. In this case, the magnetic field applying unit 80 includes ring-shaped upper and lower coils 80a, 80b installed a predetermined distance spaced apart from an outer circumference of the isolating unit 50. Preferably, the upper and lower coils 80a, 80b are substantially coaxially installed with the quartz crucible 10.

In order to form the asymmetric magnetic field G, as an example, currents of different intensities are applied to the upper and lower coils 80a, 80b. That is to say, a greater current is applied to the lower coil 80b than to the upper coil 80a, or vice versa. As an alternative, it is also possible that a current of the same intensity is applied to the upper and lower coils 80a, 80b, but the number of windings of each coil may be controlled to form an asymmetric magnetic field G. Meanwhile, it is apparent to those having ordinary skill in the art that the intensity of a magnetic field generated by the upper and lower coils 80a, 80b may be increased with keeping the R value of the asymmetric magnetic field G as it was.

Meanwhile, in order to increase a prime length of a silicon single crystal made using the CZ process, an effective segregation coefficient of dopant should be increased. Also, in order to increase the effective segregation coefficient, a thickness of a diffusion boundary layer formed in a solid-liquid interface should be increased. In order to increase the thickness of the diffusion boundary layer, it is required to stabilize a convection of a silicon melt near the solid-liquid interface. For this purpose, in the present invention, a cusp-type asymmetric magnetic field as mentioned above is applied to a quartz crucible containing a melt of dopant and silicon. Then, a thickness of the diffusion boundary layer may be increased to increase the effective segregation coefficient of dopant without using the co-doping. Accordingly, a specific electric resistance profile may be expanded in a length direction of single crystal. If the specific resistance profile is expanded as above, a prime length of a single crystal allowing manufacture of a product is increased, thereby improving productivity.

Generally, a dopant put in growing a silicon single crystal is introduced into the single crystal at an interface of the silicon melt and the single crystal. An amount of dopant introduced at this time is determined based on the effective segregation coefficient, and the effective segregation coefficient is defined as in the following equation 1.

$${k}_{e} = \frac{{C}_{s}}{{C}_{l}} \qquad Equation 1$$

Here, Cₛ is a dopant concentration in the single crystal, and Cₗ is a dopant concentration in the silicon melt. Also, an equation dominating an effective segregation coefficient induced till now is expressed in the following equation 2. The equation 2 is disclosed in “Solid state technology (April 1990 163) R. N. Thomas”, “Japanese journal of applied physics (April 1963 Vol. 2, No 4) Hiroshi Kodera”, “Journal of crystal growth (264 (2004) 550-564 D. T. Hurle” and so on.

$${k}_{e} = \frac{{k}_{0}}{[ {k}_{0} + ( 1 - {k}_{0} ) Exp ( - VT / D ) ]} \qquad Equation 2$$

Here, K₀ is an equivalent segregation coefficient, V is a growth velocity of single crystal, T is a thickness of a diffusion boundary layer, and D is a diffusion coefficient of fluid. Also, an empirical formula dominating the thickness (T) of diffusion boundary layer is expressed as the following equation 3.
T=1.6×D^{1/3}v^{1/6}ω^{-1/2} Equation 3

Here, v is a coefficient of kinematic viscosity, and w is a rotation rate of single crystal. Putting the equation 3 into the equation 2 obtains a final equation as expressed by the following equation 4.

$${k}_{e} = \frac{{k}_{0}}{[ {k}_{0} + ( 1 - {k}_{0} ) Exp ( - 1.6 \times {VD}^{- 2 / 3} {v}^{1 / 6} {ω}^{- 1 / 2} ) ]} \qquad Equation 4$$

Seeing the equation 4, it wound be found that the effective segregation coefficient is in proportion to the crystal growth velocity and the coefficient of kinematic viscosity, and in inverse proportion to the diffusion coefficient and the crystal rotation rate. However, the equation 4 is an empirical formula based on results analogized from experiments that grow a 3-inch or less single crystal into several millimeters, so it may not be applied to growth of a large-caliber single crystal over 200 mm. It is because a silicon melt is flowed in an abnormal state and thus moved in complicated patterns, and thus because analyzing an accurate fluid flow is impossible.

In the present invention, in order to satisfy the demanded quality of a semiconductor device and improve an effective segregation coefficient without deteriorating productivity, it is intended to lower a diffusion coefficient and make the diffusion boundary layer thicker. Also, to control the diffusion coefficient and the diffusion boundary layer, it was found effective to apply a cusp-type asymmetric magnetic field to the quartz crucible. It is because applying a cusp-type asymmetric magnetic field may effectively restrain abnormal flowing of fluid caused near the solid-liquid interface of the silicon melt. Such restraining of the abnormal flow is obtained since the applied asymmetric magnetic field may stably control a convection velocity and temperature distribution in the melt.

If an asymmetric magnetic field is applied in growing a silicon single crystal, a melt velocity ratio (Mvr) and a temperature difference of a silicon melt measured at a melt interface contacting with the silicon single crystal and at a position distanced from the melt interface by 50 mm satisfy the following equations 5 and 6.

$$\begin{matrix}Mvr ( \frac{{Q}^{′} z}{interface} ) < 30 ( more preferably , 15 ) & Equation 5 \\ ∇ < ( ) & Equation 6\end{matrix}$$

Mvr of Equation 5 is a convection velocity ratio of a silicon melt measured at a solid-liquid interface and at a position below the solid-liquid interface by 50 mm, and ΔTemp in the Equation 6 is a temperature difference of the silicon melt measured at a solid-liquid interface and at a position below the solid-liquid interface by 50 mm. If Mvr is controlled less than 30, more preferably less than 15, by applying a cusp-type asymmetric magnetic field, a thickness of the diffusion boundary layer may be increased to increase the effective segregation coefficient. Also, if the temperature difference is controlled less than 50K, more preferably less than 30K, by applying the asymmetric magnetic field, the thickness of the diffusion boundary layer may be increased to increase the effective segregation coefficient.

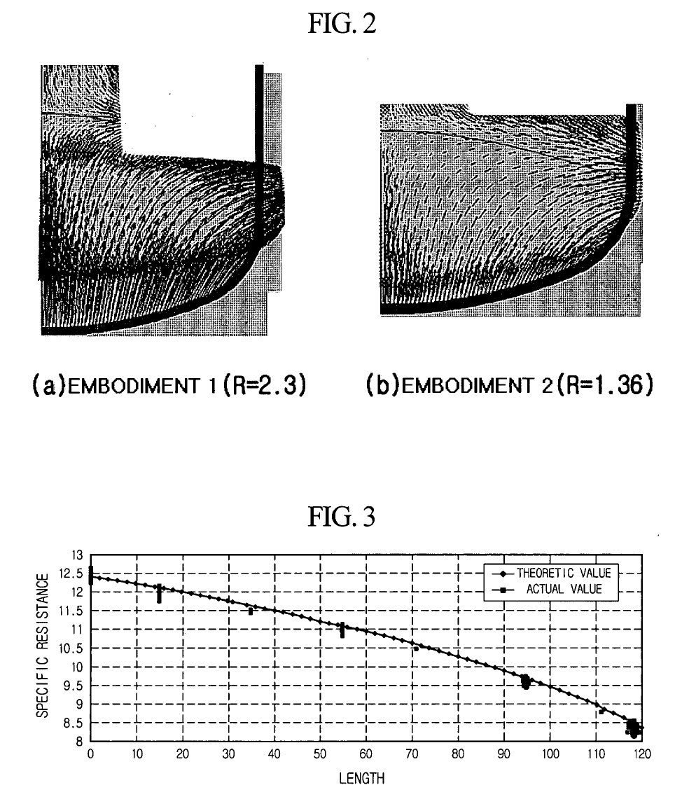

FIG. 2 shows simulation results of ZGP and magnetic field distribution around a silicon melt and a quartz crucible, in case a cusp-type asymmetric magnetic field is applied to the quartz crucible while a 8-inch silicon single crystal is growing.

Referring to FIG. 2, it would be understood that, in case R is 2.3 (the first embodiment), a density of magnetic field distribution is higher than the case that R is 1.36 (the second embodiment), the ZGP has a parabolic pattern convex upward in both of the first and second embodiments, and the ZGP moves upward as R is increased. The increase of R means that a magnetic field intensity of the lower coil is relatively increased rather than that of the upper coil. If the lower magnetic field intensity of ZGP becomes stronger than the upper magnetic field intensity, a magnetic field density is increased near the solid-liquid interface and at a boundary surface of the quartz crucible and the silicon melt. As a result, abnormal fluid flowing of the silicon melt, particularly near the solid-liquid interface, is restrained. Accordingly, the thickness of the diffusion boundary layer near the solid-liquid interface is increased, thereby increasing the effective segregation coefficient of dopant. Such increase of the effective segregation coefficient will be explained later using experimental examples.

FIG. 3 is a graph showing a theoretic specific resistance (♦) and an actually measured specific resistance (▪) according to a crystal direction of an 8-inch silicon single crystal made without applying a magnetic field thereto (a comparative example 1). In FIG. 3, points representing the actually measured specific resistances are gathered since specific resistance was measured several times while changing a measuring point on a crystal section into various positions, and many samples were used for checking reappearance. The theoretic specific resistance according to the crystal direction was obtained by theoretically calculating a specific resistance of a single crystal using factors of a radius of crystal, a weight of a seed crystal, a specific resistance of the seed crystal, a charge of polycrystalline silicon, and an effective segregation coefficient. A concrete theoretical specific resistance may be calculated using the following equations 7 and 8.

$$\begin{matrix}{ρ}_{theory} = {{ρ}_{speed} ( 1 - S )}^{( 1 - {k}_{e} )} & Equation 7 \\ S = \frac{π {R}^{2} H σ}{{M}_{charge} - {M}_{speed}} & Equation 8\end{matrix}$$

In Equation 7, ρ_{theory} is a theoretic specific resistance, ρ_{seed} is a specific resistance of a seed crystal, S is a solidification ratio, and kₑ is an effective segregation coefficient of dopant.

In Equation 8, R is a radius of an ingot, H is a height of a grown ingot, σ is a density of the ingot, M_{charge} is a weight of material input into the quartz crucible, and M_{seed} is a weight of the seed crystal.

In the comparative example 1, R=10.35 cm, M_{seed}=1560 g, ρ_{seed}=12.417 cmΩ, M_{charge}=120 kg, kₑ=0.750 and σ=2.328 g/cm³.

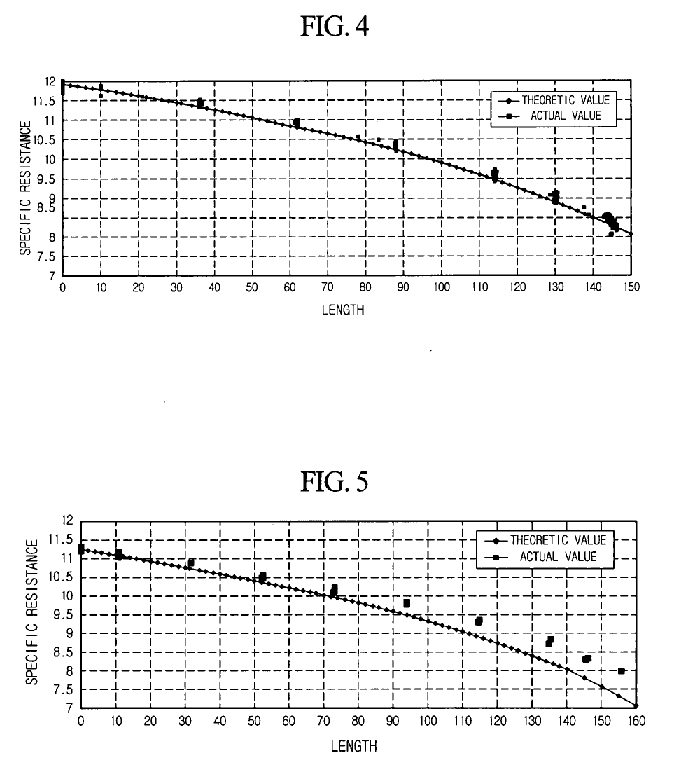

FIG. 4 is a graph showing a theoretic specific resistance (♦) and an actually measured specific resistance (▪) according to a crystal direction of an 8-inch silicon single crystal made by applying a cusp-type symmetric magnetic field (R=1) thereto (a comparative example 2). In the comparative example 2, R=10.35 cm, M_{seed}=1560 g, ρ_{seed}=11.94 cmΩ, M_{charge}=150 kg, kₑ=0.750 and σ=2.328 g/cm³. A magnetic field is applied such that ZGP is positioned right below the solid-liquid interface.

As shown in FIG. 4, if a symmetric magnetic field is applied to a quartz crucible when growing a silicon single crystal, an actually measured specific resistance is substantially not different from the theoretic specific resistance. Thus, it would be understood that the symmetric magnetic field cannot substantially increase an effective segregation coefficient, and thus a specific resistance profile cannot be controlled in a length direction of crystal.

FIG. 5 is a graph showing a theoretic specific resistance (♦) and an actually measured specific resistance (▪) according to a crystal direction of a silicon single crystal made by applying an asymmetric magnetic field (R=2.3) made according to a first embodiment of the present invention as shown in (a) of FIG. 2. In the first embodiment, R=10.35 cm, M_{seed}=1560 g, ρ_{seed}=11.25 cmΩ, M_{charge}=150 kg, kₑ=0.750 and σ=2.328 g/cm³.

Referring to FIG. 5, differently from the specific resistance comparison results of the comparative examples 1 and 2 explained above, it would be found that reduction of a specific resistance according to crystal growth is lessened such that a specific resistance profile is expanded in a length direction of crystal. In more detail, in a 0 to ½ L (L is a total length of the grown single crystal body) region in a length direction of crystal, the specific resistance is increased 0 to 15% rather than a theoretic specific resistance, and in a ½ to 1 L region, the specific resistance is increased 0 to 40% rather than the theoretic specific resistance. Accordingly, it would be understood that, by applying an asymmetric magnetic field, it is possible to control an effective segregation coefficient of dopant and also control a specific resistance profile in a length direction of crystal, and thus a prime length of a silicon single crystal may be increased.

Meanwhile, though not suggested using specific examples, it would be apparent that an effective segregation coefficient may be further increased if magnetic intensities of the upper and lower coils are increased at the same ratio though R is identical, since a magnetic field density in the silicon melt is increased.

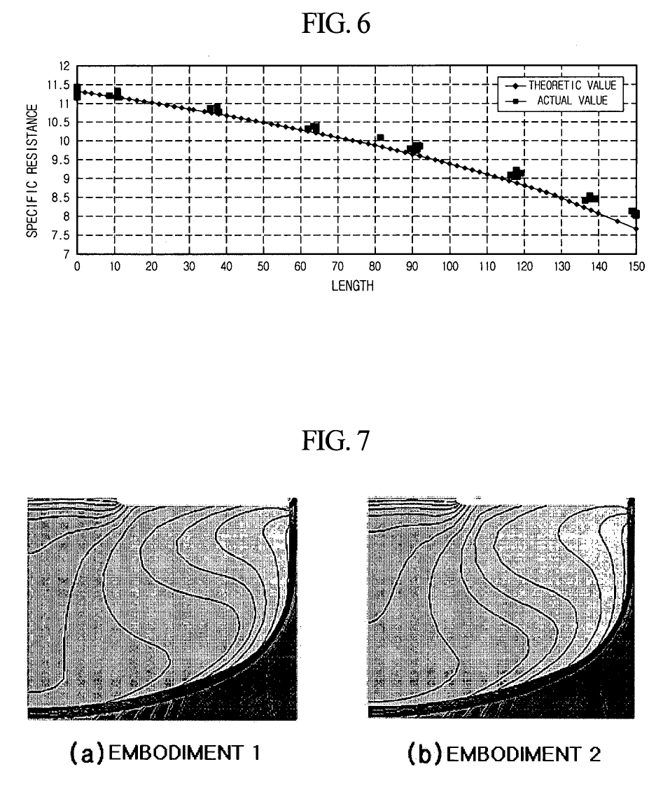

FIG. 6 is a graph showing a theoretic specific resistance (♦) and an actually measured specific resistance (▪) according to a crystal direction of an 8-inch silicon single crystal made by applying an asymmetric magnetic field (R=1.36) made according to a second embodiment of the present invention as shown in (b) of FIG. 2. In the second embodiment, R=10.35 cm, M_{seed}=1560 g, ρ_{seed}=11.33 cmΩ, M_{charge}=150 kg, kₑ=0.750 and σ=2.328 g/cm³. Also, an asymmetric magnetic field is applied such that a convex point of ZGP is positioned just below the solid-liquid interface.

Referring to FIG. 6, it would be found that a specific resistance profile is expanded in a length direction of crystal, similarly to the first embodiment. In more detail, it was observed such that, in a 0 to ½ L region in a length direction of crystal, the specific resistance is increased 0 to 10% rather than a theoretic specific resistance, and in a ½ to 1 L region, the specific resistance is increased 0 to 23% rather than the theoretic specific resistance.

Also, comparing the first and second embodiments with each other, though using an asymmetric magnetic field, it is more advantageous in controlling a specific resistance in a length direction of crystal when ZGP is positioned above the silicon melt (the first embodiment), rather than the case that R is greater and thus ZGP is positioned in the silicon melt by control of R (the second embodiment).

FIG. 7 is a graph showing simulation results of temperature distribution of a silicon melt in the first and second embodiments shown in FIG. 2, respectively. In FIG. 7, a solid line is an isothermal line, and a gap between adjacent isothermal lines is 2K. Referring to FIG. 7, an isothermal line gap of the first embodiment is greater than an isothermal line gap of the second embodiment near the solid-liquid interface. Thus, it would be understood that increasing R would reduce a temperature gradient in the silicon melt, thereby stabilizing temperature distribution. According to the graphs shown in FIGS. 5 and 6, it would be understood that, as R is increased, the specific resistance profile is expanded in a length direction of crystal, so an effective segregation coefficient of dopant may be better controlled as a temperature gradient in the silicon melt is decreased. In addition, in the case that R is increased such that ZGP is positioned above the silicon melt (the first embodiment), a temperature gradient in the silicon melt is reduced to allow stable control of temperature distribution, rather than the case that ZGP is positioned in the silicon melt (the second embodiment). If the temperature distribution is stabilized as mentioned above, it is possible to restrain abnormal fluid flowing of the silicon melt, and thus it is possible to increase a thickness of the diffusion boundary layer near the solid-liquid interface, thereby increasing an effective segregation coefficient.

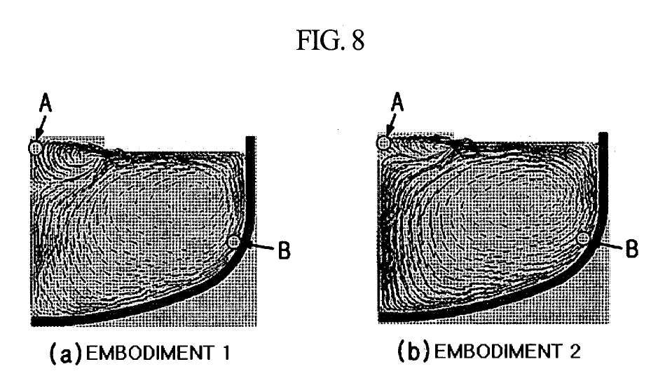

FIG. 8 is a graph showing simulation results of convection velocity distribution for the silicon melt in the first and second embodiments shown in FIG. 2, respectively. In FIG. 8, an arrow direction represents a convection direction of a silicon melt, and a length of the arrow represents a magnitude of convection velocity. Referring to FIG. 8, it would be understood that, based on the same point, a convection velocity is reduced as R is greater, and a convection velocity of the silicon melt is reduced in the case that ZGP is positioned above the silicon melt (the first embodiment) rather than the case that ZGP is positioned in the silicon melt (the second embodiment). In more detail, in the first embodiment, a melt convection velocity at a solid-liquid interface (A point) is 0.14 cm/s and a melt convection velocity at a curved point (B point) of a bottom of the sidewall is 1.21 cm/s, while in the second embodiment, a melt convection velocity at a solid-liquid interface (A point) is 0.33 cm/s and a melt convection velocity at a curved point (B point) of a bottom of the sidewall is 1.85 cm/s.

According to the graph of FIG. 8, as R is increased and as ZGP is moved upward, a convection velocity of the silicon melt is reduced to restrain abnormal flowing of the silicon melt, and thus a thickness of the diffusion boundary layer near the solid-liquid interface is increased to increase the effective segregation coefficient of dopant.

As mentioned above, by applying an asymmetric magnetic field when a silicon single crystal is grown using the CZ process, it is possible to decrease a silicon convection velocity and a temperature gradient in the silicon melt, and thus to restrain abnormal flowing of the silicon melt such that a thickness of the diffusion boundary layer near the solid-liquid interface may be controlled to increase an effective segregation coefficient of dopant, thereby capable of expanding a specific resistance profile in a length direction of crystal.

The expansion of the specific resistance profile has a relation to control of the thickness of the diffusion boundary layer, resulted from the control of a convection velocity and a temperature distribution of the silicon melt, so the specific resistance profile may be further expanded by means of additional control of a rotating speed of crystal, a flow rate of inert gas supplied to an upper portion of the silicon melt along a sidewall of crystal, a pressure of a single crystal growing chamber, and so on together with applying an asymmetric magnetic field to the quartz crucible.

Meanwhile, the first and second embodiments explained above are based on the case that R of the cusp-type asymmetric magnetic field applied to the quartz crucible is greater than 1, but it would be apparent that the present invention is not limited to the case but may be applied to the case that R is greater than 0 and smaller than 1.

Also, the present invention is not limited in kind of materials that are grown using the CZ process, but may be applied all kinds of single crystal growth. Thus, the present invention may be applied to growth of all kinds of single elements such as germanium and all kinds of single crystals of compound semiconductors including Si, Ge, GaAs, InP, LN(LiNbO₃), LT(LiTaO₃), YAG (yttrium aluminum garnet), LBO(LiB₃O₅) and CLBO(CsLiB₆O₁₀) single crystal ingot as well as a silicon single crystal.

The present invention has been described in detail. However, it should be understood that the detailed description and specific examples, while indicating preferred embodiments of the invention, are given by way of illustration only, since various changes and modifications within the spirit and scope of the invention will become apparent to those skilled in the art from this detailed description.

### APPLICABILITY TO THE INDUSTRY

According to the present invention, an asymmetric magnetic field is applied when growing a semiconductor single crystal using the CZ process, thereby controlling a convection velocity and a temperature distribution of a semiconductor melt and thus restraining abnormal flowing of the semiconductor melt. Accordingly, a thickness of a diffusion boundary layer near a solid-liquid interface is increased to increase an effective segregation coefficient of dopant, and thus a specific resistance profile is expanded in a length direction of crystal when growing not only a small- or middle-caliber semiconductor single crystal but also a large-caliber semiconductor single crystal over 200 mm. Thus, the present invention may improve productivity rather than the conventional one.

What is claimed is:

1. A method for manufacturing a semiconductor single crystal using a Czochralski (CZ) process in which a seed crystal is dip into a melt of semiconductor raw material and dopant received in a crucible, and then the seed crystal is slowly pulled upward while being rotated to grow a semiconductor single crystal,
wherein a cusp-type asymmetric magnetic field having upper and lower magnetic field intensities different from each other based on ZGP (Zero Gauss Plane) where a vertical component of the magnetic field is 0 is applied to the crucible such that a specific resistance profile, theoretically calculated in a length direction of crystal, is expanded in a length direction of crystal.

2. The method for manufacturing a semiconductor single crystal according to claim 1,
wherein the theoretically calculated specific resistance is calculated using the following equation:
$${ρ}_{theory} = {{ρ}_{speed} ( 1 - S )}^{( 1 - {k}_{e} )}$$
where ρ_{theory} is a theoretic specific resistance, ρ_{seed} is a specific resistance of the seed crystal, S is a solidification ratio, kₑ is an effective segregation coefficient of the dopant.

3. The method for manufacturing a semiconductor single crystal according to claim 1,
wherein, while a single crystal is growing, a temperature difference between a solid-liquid interface and a point spaced apart from the solid-liquid interface by 50 mm is less than 50K.

4. The method for manufacturing a semiconductor single crystal according to claim 1,
wherein, while a single crystal is growing, a ratio of a convection velocity at a solid-liquid interface to a convection velocity at a point spaced apart from the solid-liquid interface by 50 mm is less than 30.

5. The method for manufacturing a semiconductor single crystal according to claim 1,
wherein a specific resistance measured in 0 to ½ L region in a length direction of the grown semiconductor single crystal is increased 0 to 15% rather than the theoretically calculated specific resistance.

6. The method for manufacturing a semiconductor single crystal according to claim 1,
wherein a specific resistance measured in ½ L to 1 L region in a length direction of the grown semiconductor single crystal is increased 0 to 40% rather than the theoretically calculated specific resistance.

7. The method for manufacturing a semiconductor single crystal according to claim 1,
wherein a lower portion of the asymmetric magnetic field has a greater intensity than an upper portion thereof, based on ZGP.

8. The method for manufacturing a semiconductor single crystal according to claim 7,
wherein the ZGP has a parabolic pattern convex upward, and
wherein an upper vertex of the parabolic pattern is positioned above a semiconductor melt.

9. The method for manufacturing a semiconductor single crystal according to claim 1,
wherein an upper portion of the asymmetric magnetic field has a greater intensity than a lower portion thereof, based on ZGP.

10. The method for manufacturing a semiconductor single crystal according to claim 9,
wherein the ZGP has a parabolic pattern convex downward, and
wherein a lower vertex of the parabolic pattern is positioned in a semiconductor melt.

11. The method for manufacturing a semiconductor single crystal according to claim 1,
wherein the semiconductor single crystal is Si, Ge, GaAs, InP, LN(LiNbO₃), LT(LiTaO₃), YAG (yttrium aluminum garnet), LBO(LiB₃O₅) or CLBO(CsLiB₆O₁₀) single crystal.

12. An ingot of a semiconductor single crystal, grown using a CZ process in which a seed crystal is dip into a melt of semiconductor raw material and dopant received in a crucible, and then the seed crystal is slowly pulled upward while being rotated,
wherein, while the semiconductor single crystal is growing, a cusp-type asymmetric magnetic field having upper and lower magnetic field intensities different from each other based on ZGP where a vertical component of the magnetic field is 0 is applied to the crucible such that a specific resistance profile, theoretically calculated in a length direction of crystal, is expanded in a length direction of crystal.

13. The ingot of a semiconductor single crystal according to claim 12,
wherein the theoretically calculated specific resistance is calculated using the following equation:
$${ρ}_{theory} = {{ρ}_{speed} ( 1 - S )}^{( 1 - {k}_{e} )}$$
where ρ_{theory} is a theoretic specific resistance, ρ_{seed} is a specific resistance of the seed crystal, S is a solidification ratio, kₑ is an effective segregation coefficient of the dopant.

14. The ingot of a semiconductor single crystal according to claim 12,
wherein the semiconductor single crystal is manufactured by applying an asymmetric magnetic field whose lower portion has a greater intensity than an upper portion thereof, based on ZGP.

15. The ingot of a semiconductor single crystal according to claim 14,
wherein the ZGP has a parabolic pattern convex upward, and
wherein an upper vertex of the parabolic pattern is positioned above a semiconductor melt.

16. The ingot of a semiconductor single crystal according to claim 12,
wherein the semiconductor single crystal is manufactured using an asymmetric magnetic field whose upper portion has a greater intensity than a lower portion thereof, based on ZGP.

17. The ingot of a semiconductor single crystal according to claim 16,
wherein the ZGP has a parabolic pattern convex downward, and
wherein a lower vertex of the parabolic pattern is positioned in a semiconductor melt.

18. The ingot of a semiconductor single crystal according to claim 12,
wherein a specific resistance measured in 0 to ½ L region in a length direction of the grown semiconductor single crystal is increased 0 to 15% rather than the theoretically calculated specific resistance.

19. The ingot of a semiconductor single crystal according to claim 12,
wherein a specific resistance measured in ½ L to 1 L region in a length direction of the grown semiconductor single crystal is increased 0 to 40% rather than the theoretically calculated specific resistance.

20. The ingot of a semiconductor single crystal according to claim 12,
wherein the semiconductor single crystal ingot is Si, Ge, GaAs, InP, LN(LiNbO₃), LT(LiTaO₃), YAG (yttrium aluminum garnet), LBO(LiB₃O₅) or CLBO(CsLiB₆O₁₀) single crystal ingot.

21. A semiconductor wafer, manufactured using the semiconductor single crystal ingot defined in claim 12.

22. The semiconductor wafer according to claim 21,
wherein the semiconductor single crystal ingot is Si, Ge, GaAs, InP, LN(LiNbO₃), LT(LiTaO₃), YAG (yttrium aluminum garnet), LBO(LiB₃O₅) or CLBO(CsLiB₆O₁₀) single crystal ingot.
